(19) United States
(12) Patent Application Publication
(10) Pub. No.: US 2013/0154047 A1
(43) Pub. Date: Jun. 20, 2013

(54) PHOTOELECTRIC CONVERSION DEVICE AND METHOD FOR FABRICATING THE PHOTOELECTRIC CONVERSION DEVICE

(71) Applicant: SANYO Electric Co., Ltd., Osaka (JP)

(72) Inventors: Toshio YAGIURA, Osaka (JP); Satoru OGASAHARA, Osaka (JP); Kazushi ISHIKI, Osaka (JP); Ryoji NAITO, Osaka (JP)

(73) Assignee: SANYO ELECTRIC CO., LTD., Osaka (JP)

(21) Appl. No.: 13/770,707

(22) Filed: Feb. 19, 2013

Related U.S. Application Data
(63) Continuation of application No. PCT/JP2011/004509, filed on Aug. 9, 2011.

(30) Foreign Application Priority Data
Aug. 20, 2010 (JP) 2010-184726

(51) Int. Cl. H01L 31/02; H01L 31/18

(52) U.S. Cl. CPC H01L 31/02; H01L 31/18
USPC 257/443; 438/73

(57) ABSTRACT

A photoelectric conversion device includes a substrate, a plurality of photoelectric conversion cells formed on the main surface of the substrate, a current-collecting wiring formed on the plurality of photoelectric conversion cells, an output wiring connected to the current-collecting wiring, and a back-side protective member bonded to the plurality of photoelectric conversion cells via a sealing member in a manner such that the plurality of photoelectric conversion cells formed on the main surface of the substrate are interposed between the substrate and the back-side protective member via the sealing member. The current-collecting wiring and the output wiring are positioned such that the current-collecting wiring and the output wiring do not overlap with each other above the main surface of the substrate.

### CROSS-REFERENCE TO RELATED APPLICATIONS

This application is based upon and claims the benefit of priority from the prior Japanese Patent Application No. 2010-184726, filed on Aug. 20, 2010, and International Patent Application No. PCT/JP2011/004509, filed on Aug. 9, 2011, the entire content of each of which is incorporated herein by reference.

### BACKGROUND OF THE INVENTION

1. Field of the Invention

The present invention relates to a photoelectric conversion device and a method for fabricating the photoelectric conversion device.

2. Description of the Related Art

A photoelectric conversion device where an amorphous semiconductor thin film, microcrystalline semiconductor thin film, and the like are laminated is used as a power generation system using solar light.

As illustrated in FIG. 11, a photoelectric conversion device 300 is configured such that transparent electrode layers 112, photoelectric conversion layers 114 and back-side electrodes 116 are formed on a glass substrate 110 and thereby a plurality of photoelectric conversion cells 150 are formed thereon. In order to collect the power generated, a current-collecting wiring 118 is connected to a back-side electrode 116 located at an end of the glass substrate 110. An output wiring 122 is connected to the current-collecting wiring 118 and thereby the power generated is outputted to the outside.

A sealing member 128 such as ethylene vinyl acetate (EVA) is placed on the photoelectric conversion cells 150 formed on the glass substrate 110, thereby forming the photoelectric conversion device 300. Here, a current-collecting wiring 118, an insulating member 120 and an output wiring 122 are held and sealed between the photoelectric conversion cells 150 and a back-side protective member 130 by the sealing member 128.

In the above-described photoelectric conversion device 300, a single-layered body made of a resin, such as polyethylene terephthalate (PET), or a layered product with a metallic foil held by the resin is used as the back-side protective member 130. The single-layered body or layered product formed of such resin and the like does not serve as a structure. Thus, a frame formed of aluminum or the like is attached around the photoelectric conversion device 300 to increase the strength of the photoelectric conversion device 300.

However, provision of the frame formed of aluminum or the like adds to the cost of the photoelectric conversion device 300. Thus, a method is proposed where glass is used for the back-side protective member 130 and thereby the back-side protective member 130 can also serve as the structure.

### SUMMARY OF THE INVENTION

In the photoelectric conversion device 300, the current-collecting wiring 118 and the output wiring 122 are connected to each other in an overlapped manner and therefore a raised portion is formed in a joint region 170 where the current-collecting wiring 118 is connected to the output wiring 122 over the glass substrate 110. If glass is used as the back-side protective member 130, the back-side protective member 130 will not be flexibly deformed according to the irregularity caused by the raised portion, unlike the resin or the like. Thus, when a pressure is applied to the glass substrate 110 from a back-side protective member 130 side in a vacuum laminating process carried out when a module is to be formed, the force is exerted, in a concentrated manner, on the back-side protective member 130 near the raised portion. Thus the back-side protective member 130 may be warped and a crack may occur. This creates a problem of reduced yield.

A photoelectric conversion device according to one embodiment of the present invention includes: a substrate; a plurality of photoelectric conversion cells formed on a main surface of the substrate; a current-collecting wiring formed on the plurality of photoelectric conversion cells; an output wiring connected to the current-collecting wiring; and a back-side protective member bonded to the plurality of photoelectric conversion cells via a sealing member in a manner such that the plurality of photoelectric conversion cells formed on the main surface of the substrate are interposed between the substrate and the back-side protective member via the sealing member, wherein the current-collecting wiring and the output wiring are positioned such that the current-collecting wiring and the output wiring do not overlap with each other above the main surface of the substrate.

A method, for fabricating a photoelectric conversion device, according to another embodiment of the present invention includes: forming a plurality of photoelectric conversion cells on a main surface of a substrate; forming a current-collecting wiring for collecting currents generated by the plurality of photoelectric conversion cells; forming an output wiring for outputting power generated by the current-collecting wiring to the outside; bonding a back-side protective member to the plurality of photoelectric conversion cells via sealing member in a manner such that the plurality of photoelectric conversion cells formed on the main surface of the substrate are interposed between the substrate and the back-side protective member via the sealing member, wherein the current-collecting wiring and the output wiring are placed on the main surface of the substrate and connected to each other in a manner such that the current-collecting wiring and the output wiring do not overlap with each other.

### BRIEF DESCRIPTION OF THE DRAWINGS

Embodiments will now be described by way of examples only, with reference to the accompanying drawings which are meant to be exemplary, not limiting, and wherein like elements are numbered alike in several Figures in which:

FIG. 1 is a plane view showing a structure of a photoelectric conversion device according to a first embodiment of the present invention;

FIG. 2 is a cross-sectional view showing a structure of a photoelectric conversion device according to a first embodiment of the present invention;

FIG. 3 is a cross-sectional view showing a structure of a photoelectric conversion device according to a first embodiment of the present invention;

FIG. 4 is a cross-sectional view showing a structure of a photoelectric conversion device according to a first embodiment of the present invention;

FIG. 5 is an enlarged plane view showing a characterizing portion of a photoelectric conversion device according to another exemplary embodiment of a first embodiment of the present invention;

FIG. 6 is an enlarged plane view showing a characterizing portion of a photoelectric conversion device according to still another exemplary embodiment of a first embodiment of the present invention;

FIGS. 7A to 7E are cross-sectional views to explain a method for manufacturing a photoelectric conversion device according to a first embodiment of the present embodiment;

FIGS. 8F to 8H are cross-sectional views to explain a method for manufacturing a photoelectric conversion device according to a first embodiment of the present embodiment;

FIG. 9 is an enlarged plane view showing a characterizing portion of a photoelectric conversion device according to a second embodiment of the present invention;

FIG. 10 is a cross-sectional view showing a characterizing portion of a photoelectric conversion device according to a second embodiment of the present invention;

FIG. 11 is a cross-sectional view showing a structure of a photoelectric conversion device according to the conventional practice;

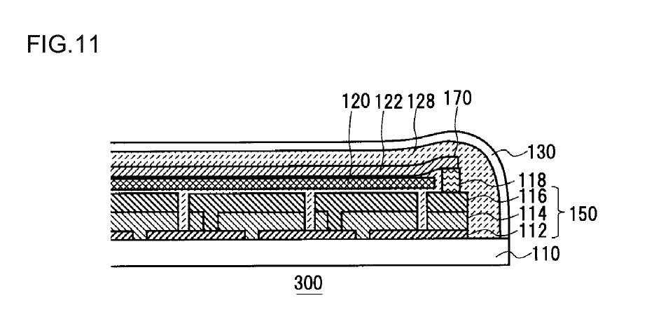

FIG. 12 is an enlarged plane view showing a characterizing portion in a structure of a photoelectric conversion device according to a first modification of a first embodiment of the present invention;

FIG. 13 is an enlarged plane view showing a characterizing portion in a structure of a photoelectric conversion device according to a second modification of a first embodiment of the present invention;

FIG. 14 is an enlarged plane view showing a characterizing portion in a structure of a photoelectric conversion device according to a third modification of a first embodiment of the present invention;

FIG. 15 is an enlarged plane view showing a characterizing portion in a structure of a photoelectric conversion device according to a fourth modification of a first embodiment of the present invention; and

FIG. 16 is an enlarged plane view showing a characterizing portion in a structure of a photoelectric conversion device according to a fifth modification of a first embodiment of the present invention.

### DETAILED DESCRIPTION OF THE INVENTION

Hereinbelow, the preferred embodiments will be described with reference to the accompanying drawings. Note that in all of the figures the same reference numerals are given to the same components and the description thereof is omitted as appropriate.

### First Embodiment

(Structure of Photoelectric Conversion Device)

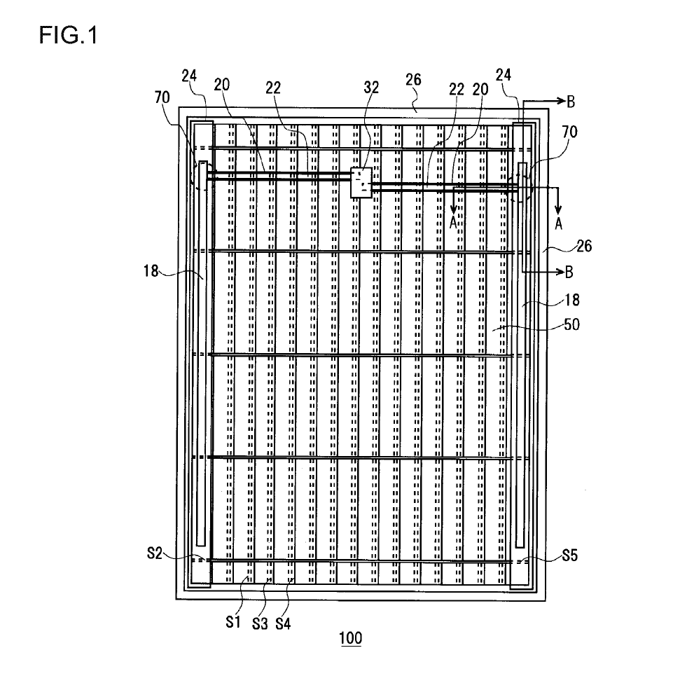

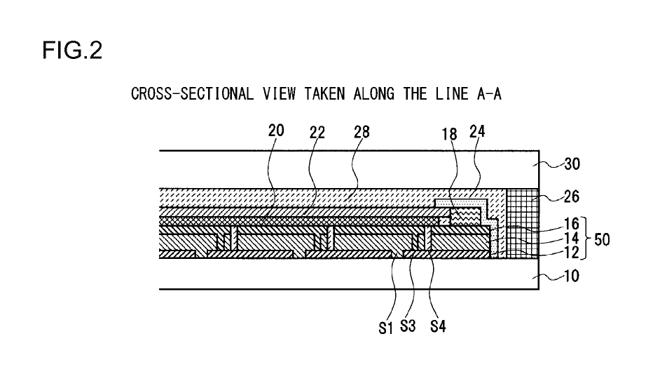

FIG. 1 to FIG. 3 each shows a structure of a photoelectric conversion device 100 according to a first embodiment of the present invention. FIG. 1 is a plane view as viewed from a side opposite to a light-receiving surface of the photoelectric conversion device 100. FIG. 2 is a cross-sectional view taken along the line A-A of FIG. 1.

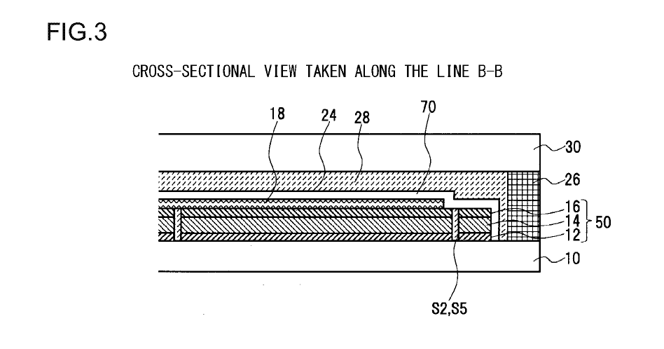

FIG. 3 is a cross-sectional view taken along the line B-B of FIG. 1. For clarity of the structure of the photoelectric conversion device 100, a sealing member 28 and a back-side protective member 30 are not depicted in FIG. 1 and portions that are actually not visible due to the overlapping are indicated with dotted lines in FIG. 1. Also, for clarity of the structure thereof, the dimensions of each part is scaled differently from the actual dimensions in FIG. 1 to FIG. 3.

As illustrated in FIG. 1 to FIG. 3, the photoelectric conversion device 100 is configured by including a substrate 10, a transparent electrode layer 12, a photoelectric conversion layer 14, a back-side electrode 16, a current-collecting wiring 18, an insulating member 20, an output wiring 22, an insulating coating material 24, an end-sealing material 26, a sealing member 28, a back-side protective member 30, and a terminal box 32.

The substrate 10 is a member used to support the photoelectric conversion device 100, and glass is used for the substrate 10.

The transparent electrode layers 12 are configured, in a rectangular strip shaped manner, on a main surface of the substrate 10. In the transparent electrodes 12, a first slit S1 is formed so that a plurality of photoelectric conversion cells 50 can be configured by connecting them in series. Also, the photoelectric conversion cells 50 are patterned in a rectangular strip shape. Also, a second slit S2 is formed so that the photoelectric conversion cells 50 can be configured in parallel with each other in a divided manner. The transparent electrode layer 12 may preferably be made of at least one of transparent conductive oxides or made of a combination of two or more of transparent conductive oxides in which tin oxide (SnO₂), zinc oxide (ZnO), indium tin oxide (ITO), or the like is doped with tin (Sn), antimony (Sb), fluorine (F), aluminum (Al) or the like. Among them, zinc oxide in particular is high in translucency, low in resistivity, and excellent in the plasma-resistant characteristics. Thus, zinc oxide is used for the transparent electrode layers 12 in the present embodiment.

The photoelectric conversion layer 14 is configured such that silicon-based thin films, which are a p-type layer, an i-type layer, and an n-type layer, are stacked on the transparent electrode layer 12 in this order. The photoelectric conversion layer 14 may be a thin-film photoelectric conversion layer such as an amorphous silicon thin-film photoelectric conversion layer and a microcrystalline silicon thin-film photoelectric conversion layer. Also, the photoelectric conversion layer 14 may be a photoelectric conversion layer of tandem type or triple type where such the thin-film photoelectric conversion layers are laminated.

The back-side electrode 16 is formed on top of the photoelectric conversion layer 14. The back-side electrode 16 may be a single-layered body or layered produce having an electric conductivity and may preferably be configured such that a transparent conductive oxide and a reflective metal are stacked in this order. The transparent conductive oxide as used herein may be a transparent conductive oxide, such as tin oxide, zinc oxide, or indium tin oxide (ITO), or such a transparent conductive oxide doped with an impurity. For example, the transparent conductive oxide may be zinc oxide doped with aluminum as an impurity. The reflective metal as used herein may be a metal such as silver (Ag) or aluminum (Al). It is preferable that asperities for enhancing the effect of trapping the light are provided in at least one of the transparent conductive oxide and the reflective metal. In the present embodiment, silver, which is laminated on zinc oxide as the reflective metal, functions as the back-side electrode 16.

In the photoelectric conversion layer 14, a third slit S3, which extends in a direction of the first slit S1, is formed such that the transparent electrode 12 is exposed. Also, the photoelectric conversion layer 14 is buried underneath the back-side electrode 16. Hence, the transparent electrode 12 and the back-side electrode 16 are electrically connected to each other. Further, in the photoelectric conversion layer 14 and the back-side electrode 16, a fourth slit S4, which extends in a first slit S1 extending direction, is formed. More specifically, the fourth slit S4 is formed on a side opposite to the first slit S1 relative to the third slit S3, so that the a plurality of photoelectric conversion cells 50 are configured in series with each other.

The current-collecting wirings 18 are formed on top of the back-side electrodes 16 located at both ends of the photoelectric conversion device 100. The current-collecting wirings 18 are interconnection lines used to collect the current generated by the photoelectric conversion cells 50 divided in parallel. Thus the current-collecting wiring 18 extends along the first slit S1 extending direction of the photoelectric conversion layer 14. With the current-collecting wiring 18, the positive electrodes of a plurality of photoelectric conversion cells 50 connected in series are connected to each other, and the negative electrodes thereof are connected to each other. The current-collecting wiring as used herein may be a copper wiring coated with solder whose width and thickness are 2 mm and 200 μm, respectively.

Then, the insulating member 20 is disposed in order to form an electrical insulation between the output wiring 22 described later and the back-side electrode 16. The insulating member 20 extends, on top of the back-side electrode 16, from near the current-collecting wiring 18 provided along a distal edge of the photoelectric conversion device 100 to the placement position of the terminal box 32 in the center thereof. And the insulating member 20 extends along a second slit S2 extending direction in a manner such that the insulating member 20 lies across the fourth slit S4. As illustrated in FIG. 1, the insulating member 20 extends horizontally from near the current-collecting wirings 18 at the both ends towards the terminal box 32. In the present embodiment, a PET tape is used as the insulating member 20 and is arranged at a predetermined position in such a manner to be bonded to the back-side electrode 16.

The insulating member 20 may preferably be formed of an insulating material whose resistivity is 10¹⁶ (Ωcm) or above. Such an insulating material constituting the insulating member 20 may preferably be polyester (PE), polyethylene terephthalate (PET), polyethylene naphthalate (PEN), polyimide (PI), or polyvinyl fluoride (PVF), for instance. Also, the insulating member 20 may preferably be of a tape-, sheet- or film-shaped and be one to which an adhesive is applied on the reverse side in a seal shape. Thus a PET tape is used as the insulating member 20 in the present embodiment.

As illustrated in FIG. 1, the output wiring 22 extends, on top of the insulating member 20, from the current-collecting wirings 18 at the both ends towards the center of the photoelectric conversion device 100 along the second slit S2 extending direction thereof. The insulating member 20 is interposed between the current-collecting wiring 18 and the back-side electrode 16, thereby keeping an electric insulation between the output wiring 22 and the back-side electrode 16. At the same time, one end of the output wiring 22 extends to a sidewall of the current-collecting wiring 18 and therefore the output wiring 22 is electrically connected to the current-collecting wiring 18. The other end of the output wiring 22 connects to an electrode terminal inside the terminal box 32 described later. Thereby, the electric power generated by a plurality of photoelectric conversion cells 50 is delivered to outside the photoelectric conversion device 100.

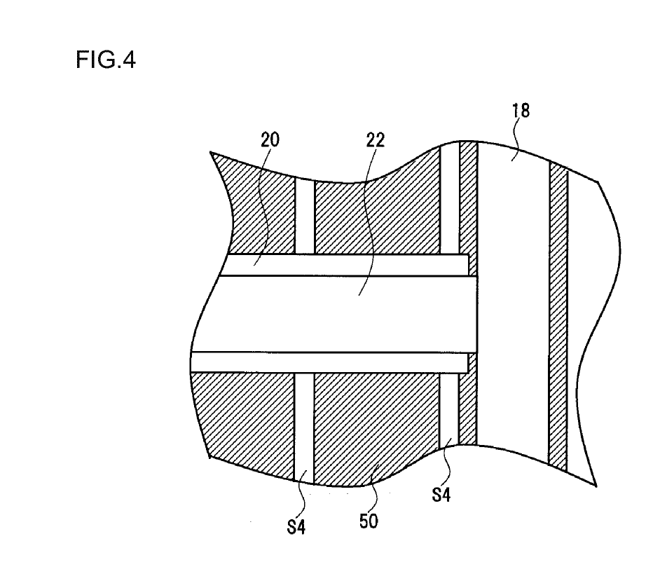

As illustrated in FIG. 2 and FIG. 4, in the present embodiment, the sidewall of the current-collecting wiring 18 and the sidewall of the output wiring 22 are positioned in contact with each other. That is, a surface of the current-collecting wiring 18 vertical to the main surface of the substrate 10 and a surface of the output wiring 22 vertical to the main surface thereof are in contact with each other and therefore the current-collecting wiring 18 and the output wiring 22 are electrically connected to each other. Thus, the current-collecting wiring 18 and the output wiring 22 are positioned such that the current-collecting wiring 18 and the output wiring 22 do not overlap with each other above the main surface of the substrate 10 in a region 70 where the current-collecting wiring 18 and the output wiring 22 of FIG. 1 are connected to each other. Note that the surface of the current-collecting wiring 18 and the surface of the output wiring 22 being in contact with each other includes a state where the current-collecting wiring 18 and the output wiring 22 are electrically connected to each other such that they comes into contact indirectly with each other through the medium of other materials held therebetween such as a solder and conductive paste between the surfaces thereof. In the present embodiment, a copper wiring coated with a solder whose width and thickness are 4 mm and 40 μm, respectively is used as the output wiring 22. In such a case, the solder is held between the copper wirings of the respective constituent materials of the current-collecting wiring 18 and the output wiring 22, so that the physical contact and the electric conductivity therebetween can be ensured.

The insulating coating material 24 is provided so that the insulating coating material 24 can partially cover at least the transparent electrode 12, the photoelectric conversion layer 14, the back-side electrode 16, the current-collecting wiring 18 and the output wiring 22 located near the end-sealing material 26 described later.

As illustrated in FIG. 2 and FIG. 3, in the present embodiment, the insulating coating material 24 extends in the first slit S1 extending direction of the photoelectric conversion layer 14 so that the insulating coating material can cover ends of the transparent electrode 12, the photoelectric conversion layer 14, the back-side electrode 16, the current-collecting wiring 18 and the output wiring 22. More specifically, the insulating coating material 24 is disposed such that the insulating coating material 24 cover the entire surface of the current-collecting wiring 18, covers end portions of the transparent electrode 12, the photoelectric conversion layer 14 and the back-side electrode 16, and partially covers the surface of the output wiring 22.

The insulating coating material 24 may preferably be formed of an insulating material whose resistivity is 10¹⁶ (Ωcm) or above. Such an insulating material constituting the insulating coating material 24 may preferably be PE, PET, PEN, PI, or PVF, for instance. Also, the insulating coating material 24 may preferably be of a tape-, sheet- or film-shaped and be one to which an adhesive is applied on the reverse side in a seal shape. Thus a PET tape is used as the insulating coating material 24 in the present embodiment.

The end-sealing material 26 is disposed in a region where a photoelectric conversion cell 50 at the distal periphery of the photoelectric conversion device 100 is not formed. Here, such a region where the end-sealing material 26 is to be provided is about 7 mm to about 15 mm in width. Assume herein that the end-sealing material 26 is formed of an insulating material whose resistivity is 10¹⁰ (Ωcm) or above. Also, the end-sealing material 26 may preferably be formed of a substance, whose permeability of water is low, in order to prevent the moisture content from entering from the ends of the photoelectric conversion device 100. In particular, the end-sealing material 26 may preferably be formed of a substance, whose permeability of water is lower than that of the sealing member 28. Further, the end-sealing material 26 may preferably have elasticity by which to mitigate a force or pressure occurring in the photoelectric conversion device 100 when a mechanical force is applied to the end portion of the photoelectric conversion device 100. For example, an epoxy-based resin or butyl-based resin may preferably be used for the end-sealing material 26. More specifically, a hot-melt butyl is preferably used since it can be easily applied and bonded at high temperature. Note that the end-sealing material 26 is formed such that the width thereof is about 6 mm to about 10 mm and the thickness thereof is greater than that of the sealing member 28 by about 0.05 mm to about 0.2 mm.

Regions surrounded by the end-sealing material 26 are sealed by the substrate 10 and the back-side protective member 30. The back-side protective member 30 is preferably formed of a substance that has electrically insulating properties, is low in the permeability of water and is high in corrosion resistance.

The sealing member 28 fills the regions sealed by the substrate 10, the end-sealing material 26 and the back-side protective member 30. An environmentally-resistant substance is often used as the back-side protective member 30. In the present embodiment, glass is used as the back-side protective member 30. Assume herein that the sealing member 28 is an insulating material. More specifically, the sealing member 28 is preferably an insulating resin whose resistivity is about 10¹⁴ (Ωcm) and may preferably be ethylene-vinyl acetate copolymer (EVA) or polyvinyl butyral (PVB), for instance. Thus, EVA is used for the sealing member 28 in the present embodiment.

Then, the output wiring 22 is led out from the back-side protective member 30 and is connected to the terminal box 32 formed on the back-side protective member 30.

In this manner, the photoelectric conversion device 100 according to the present embodiment is configured.

Though a glass substrate is used as the substrate 10 in the above-described embodiment, this should not be considered as limiting and the material used for the substrate 10 may be arbitrary as long as it has permeability at least in a visible light wavelength region so that light can enter from a substrate 10 side in the photoelectric conversion device 100. Accordingly, a plastic substrate or the like may be applicable, for instance.

In the above-described embodiment, the photoelectric conversion layer 14 has a p-i-n junction structure but this should not be considered as limiting and, for example, a pn junction may constitute the basic structure. Further, for example, a photoelectric conversion layer formed of a non-silicon-based substance such as cadmium telluride, CIS (copper, indium and selenium) or CIGS (copper, indium, gallium and selenium) may be used instead of the silicon-based photoelectric conversion layer used in the above-described examples.

In the above-described embodiment, the current-collecting wirings 18 are formed on the photoelectric conversion cells 50 at the both ends of the photoelectric conversion device 100. However, the position in which the current-collecting wirings 18 are to be provided is not limited to the photoelectric conversion cells 50 at the both ends of the photoelectric conversion device 100.

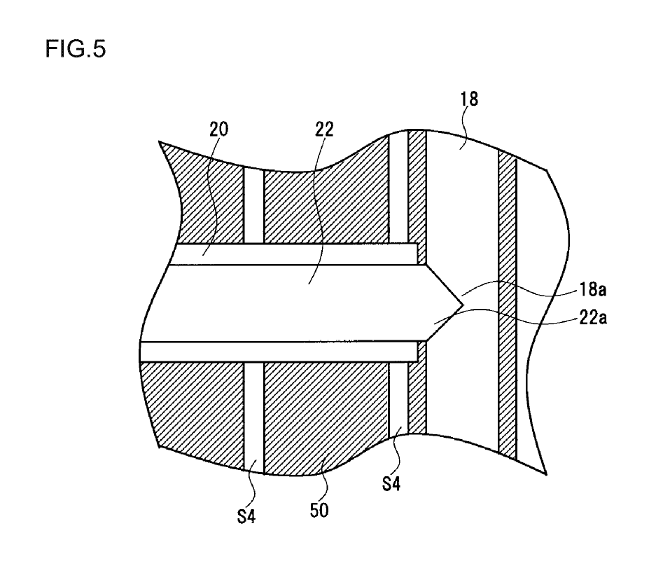

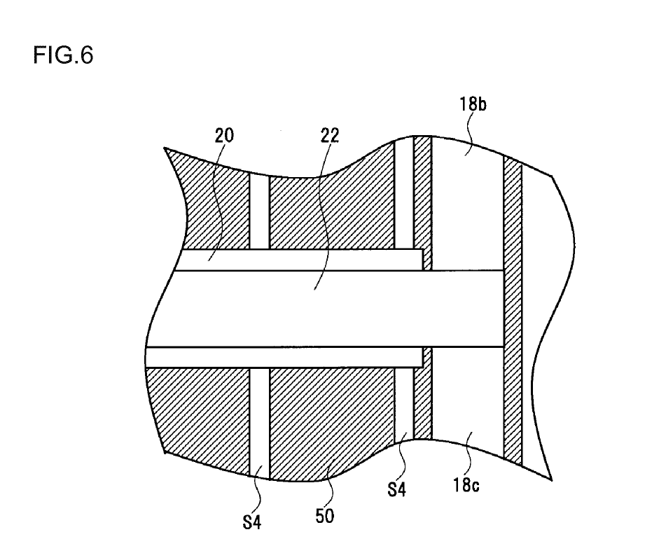

In the present embodiment, the output wiring 22 is connected to the current-collecting wiring 18 such that a flat surface of the ribbon-shaped output wiring 22 comes in contact with a flat sidewall of the ribbon-shape current-collecting wiring 18 that extends on top of the photoelectric conversion cell 50. However, this should not be considered as limiting. For example, as illustrate in FIG. 5, the current-collecting wiring 18 has a connecting component 18a which is recessed from a side (edge) of the current-collecting wiring 18 facing the center of the substrate 10. And the connecting component 18a is formed in a part of the current-collecting wiring 18 with which the output wiring 22 is connected. The output wiring 22 has a connecting component 22a corresponding to the connecting component 18a. Here, the connecting component 18a of the current-collecting wiring 18 and the connecting component 22a of the output wiring 22 are arranged so that they match and they can be firmly locked with each other, and the connecting component 18a and the connecting component 22a may form a T-shape wiring. Further, as illustrated in FIG. 6, the output wiring 22 may be placed between two ribbon-shaped current-wirings 18b and 18c on the photoelectric conversion cell 50, thereby forming a T-shape wiring.

Furthermore, the current-collecting wiring 18 and the output wiring 22 may be such that at least one of the current-collecting wiring 18 and the output wiring 22 has asperities on a joint surface between the current-collecting wiring 18 and the output wiring 22. With the asperities formed on at least one of the current-collecting wiring 18 and the output wiring 22, much solder can be held and kept in the joint surface. Thus, the current-collecting wiring 18 and the output wiring 22 can be connected to each other more reliably through such much solder placed in the joint surface.

“At least one of the current-collecting wiring 18 and the output wiring 22 has asperities on a joint surface between the current-collecting wiring 18 and the output wiring 22” as used herein may mean as follows. That is, the respective joint surfaces of the current-collecting wiring 18 and the output wiring 22 are such that the surfaces thereof are of a shape that allows the generation of gaps in a joint area when the current-collecting wiring 18 and the output wiring 22 are connected with each other. For example, the joint surface (side surface) of at least one of the current-collecting wiring 18 and the output wiring 22 may be tilted and the joint surface of the current-collecting wiring 18 may not be parallel to the joint surface of the output wiring 22. Also, a curved surface may be formed on the joint surface of at least one of the current-collecting wiring 18 and the output wiring 22.

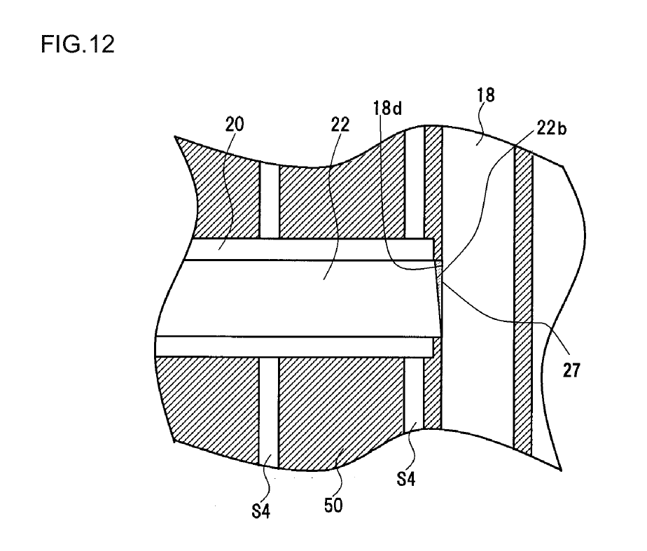

A description is given hereunder of modifications of the shape of the joint surface of the current-collecting wiring 18 and the output wiring 22 of the first embodiment. FIG. 12 is an enlarged plane view showing a characterizing portion in a structure of the photoelectric conversion device according to a first modification of the first embodiment of the present invention.

A side surface 22b of an output wiring 22 shown in FIG. 12 is tilted on a tip side of the output wiring 22 facing the current-collecting wiring 18. Accordingly, when the output wiring 22 and the current-collecting wiring 18 are connected with each other, the side surface 22b of the output wiring 22 is not parallel to a side surface 18d of the current-collecting wiring 18. This creates a space or gap between the side surface 22b of the output wiring 22 and the side surface 18d of the current-collecting wiring 18, so that much solder 23 can be held and kept in the space therebetween. Hence, the current-collecting wiring 18 and the output wiring 22 are connected to each other more reliably through such much solder 23 placed in the space therebetween.

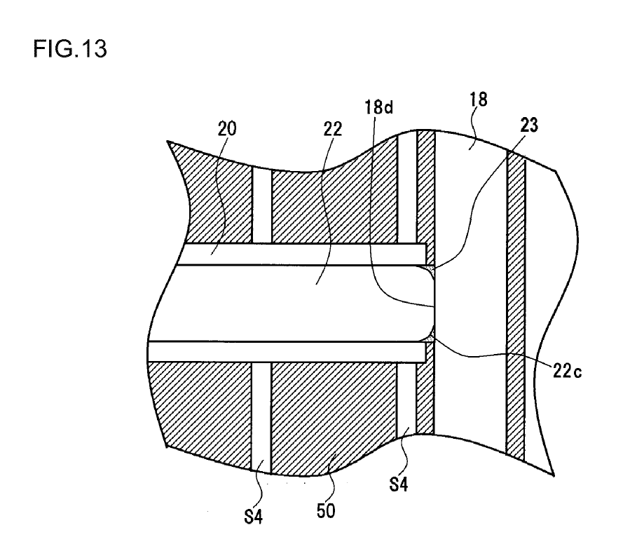

FIG. 13 is an enlarged plane view showing a characterizing portion in a structure of the photoelectric conversion device according to a second modification of the first embodiment of the present invention.

An output wiring 22 shown in FIG. 13 is such that a corner 22c thereof is rounded on the tip side of the output wiring 22 facing the current-collecting wiring 18. Accordingly, when the output wiring 22 and the current-collecting wiring 18 are connected with each other, a space or gap is created between the corner 22c of the output wiring 22 and the side surface 18d of the current-collecting wiring 18. Thus, much solder 23 can be held and kept in the space therebetween. Hence, the current-collecting wiring 18 and the output wiring 22 are connected to each other more reliably through such much solder 23 placed in the space therebetween.

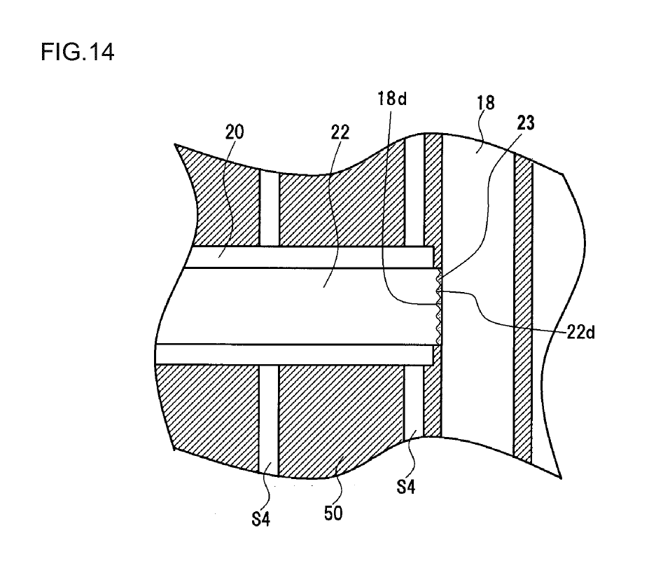

FIG. 14 is an enlarged plane view showing a characterizing portion in a structure of the photoelectric conversion device according to a third modification of the first embodiment of the present invention.

A side surface 22d of an output wiring 22 shown in FIG. 14 on the tip side of the output wiring 22 facing the current-collecting wiring 18 is processed to have asperities. Accordingly, when the output wiring 22 and the current-collecting wiring 18 are connected with each other, a space or gap is created between the side surface 22d of the output wiring 22 and the side surface 18d of the current-collecting wiring 18. Thus, much solder 23 can be held and kept in the space therebetween. The current-collecting wiring 18 and the output wiring 22 are connected to each other more reliably through such much solder 23 placed in the space therebetween.

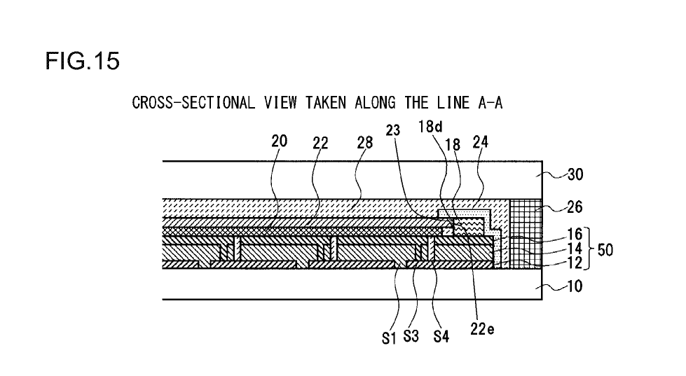

FIG. 15 is an enlarged plane view showing a characterizing portion in a structure of the photoelectric conversion device according to a fourth modification of a first embodiment of the present invention.

In the cross section of an output wiring 22 shown in FIG. 15, a side surface 22e of the output wiring 22 is tilted on a tip side of the output wiring 22 facing the current-collecting wiring 18. More specifically, the side surface 22e thereof is tilted such that an end of the output wiring 22 at a substrate 10 side is closer to the current-collecting wiring 18 than an end of the output wiring 22 at a back-side protective member 30 side. Note that the side surface 22e thereof may be tilted such that the end of the output wiring 22 at the back-side protective member 30 side is closer to the current-collecting wiring 18 than the end of the output wiring 22 at the substrate 10 side. With the side surface 22e of such a shape formed, the side surface 22e of the output wiring 22 is not parallel to the side surface 18d of the current-collecting wiring 18, when the output wiring 22 and the current-collecting wiring 18 are connected with each other. This creates a space or gap between the side surface 22e of the output wiring 22 and the side surface 18d of the current-collecting wiring 18, so that much solder 23 can be held and kept in the space therebetween. Hence, the current-collecting wiring 18 and the output wiring 22 are connected to each other more reliably through such much solder 23 placed in the space therebetween.

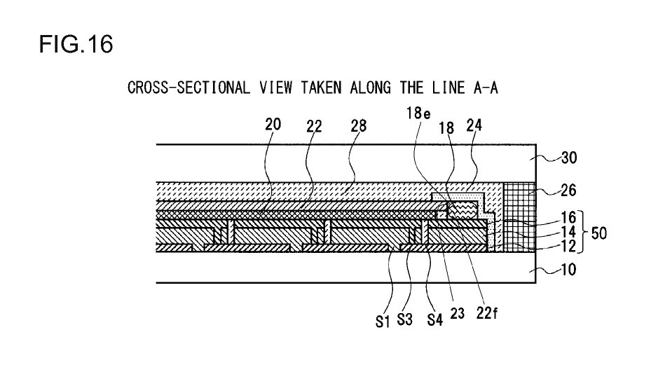

FIG. 16 is an enlarged plane view showing a characterizing portion in a structure of the photoelectric conversion device according to a fifth modification of the first embodiment of the present invention.

In the cross section of a current-collecting wiring 18 shown in FIG. 16, the current-collecting wiring 18 is such that a corner 18e thereof facing the output wiring 22 is rounded. Accordingly, when the output wiring 22 and the current-collecting wiring 18 are connected with each other, a space or gap is created between the side surface 22f of the output wiring 22 and the corner 18e of the current-collecting wiring 18. Thus, much solder 23 can be held and kept in the space therebetween. Hence, the current-collecting wiring 18 and the output wiring 22 are connected to each other more reliably through such much solder 23 placed in the space therebetween.

(A Method for Fabricating a Photoelectric Conversion Device)

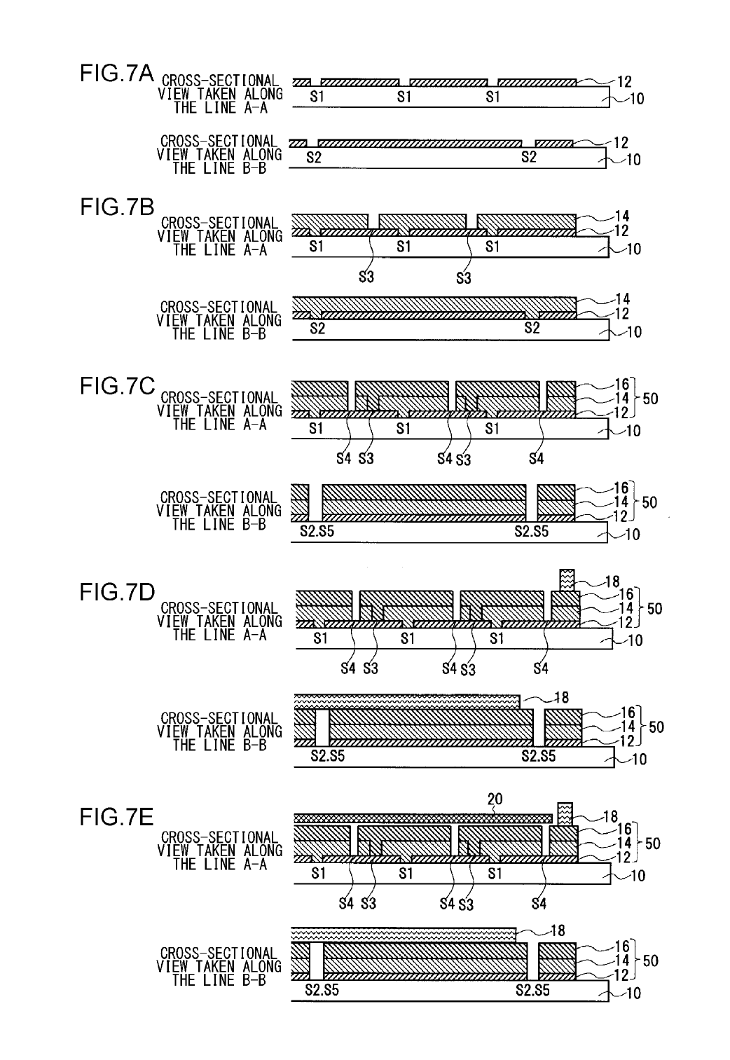

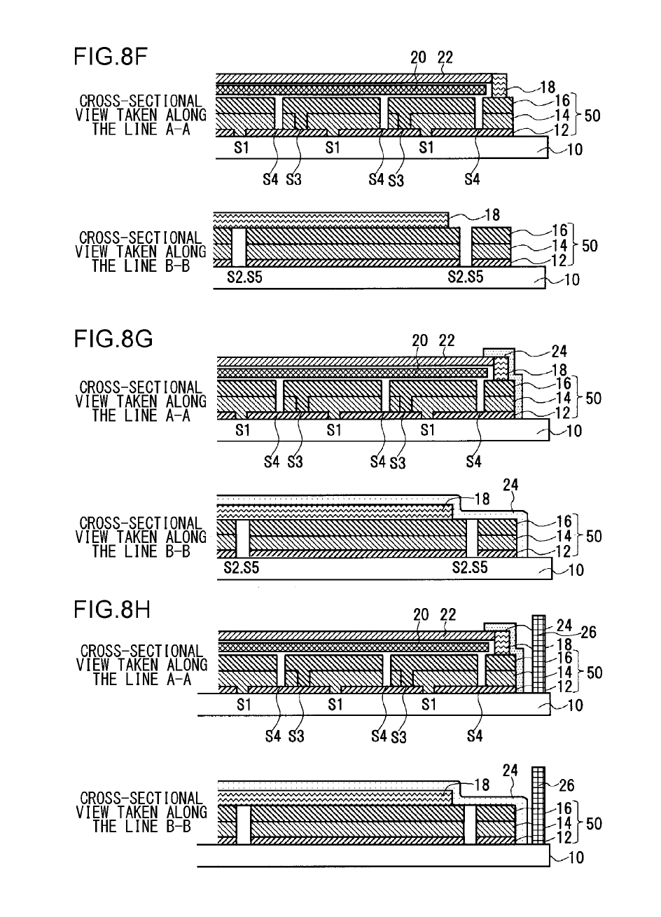

A description is given hereinbelow of a method for fabricating a photoelectric conversion device 100 according to the first embodiment using FIGS. 7A to 7E and FIGS. 8F to 8H. FIGS. 7A to 7E are cross-sectional views taken along the line A-A of FIG. 1 to explain a method for manufacturing the photoelectric conversion device, and FIGS. 8F to 8H are cross-sectional views taken along the line B-B of FIG. 1 to explain a method for manufacturing the photoelectric conversion device.

As illustrated in FIG. 7A, a substrate 10 made of glass is prepared. Then, transparent electrode layer 12 is formed on the substrate 10 by use of a sputtering method or a CVD method. The transparent electrode layer 12 is irradiated with laser and thereby patterned in a rectangular strip shape. In the present embodiment, the first slit S1 is formed along the vertical direction of FIG. 1 so as to segmentalize the transparent electrode layer 12 in order that the photoelectric conversion cells 50 can be configured such that they are connected in series. Also, in order that the photoelectric conversion cells 50 can be configured such that they are connected in parallel, the transparent electrode layer 12 is patterned in a rectangular strip shape in a direction orthogonal to the first slit S1 that is used to form the photoelectric conversion cells 50 are connected in series and is then segmentalized. The transparent electrode layer 12 may be patterned using YAG laser whose wavelength is 1,064 nm, whose energy density is 13 J/cm², and whose pulse frequency is 3 kHz, for instance.

Then, as illustrated in FIG. 7B, a photoelectric conversion layer 14 is formed on the transparent electrode layer 12. In the present embodiment, formed is a photoelectric conversion layer 14 in which an amorphous silicon thin-film photoelectric conversion layer and a microcrystalline silicon thin-film photoelectric conversion layer are laminated sequentially. The amorphous silicon thin-film photoelectric conversion layer and the microcrystalline silicon thin-film photoelectric conversion layer may be formed using a plasma-enhanced chemical vapor deposition (CVD method). In this plasma-enhanced CVD method, a mixed gas in which a silicon-containing gas, such as silane (SiH₄), disilane (Si₂H₆) and dichlorosilane (SiH₂Cl₂), a p-type dopant-containing gas, such as diborane (B₂H₆), an n-type dopant-containing gas, such as phosphine (PH₃), and a diluent gas, such as hydrogen (H₂) are mixed together, is turned into plasma so as to form a film. For example, a parallel plate type RF plasma CVD method using a high frequency power of 13.56 MHz may preferably be used as the plasma-enhanced CVD method.

To achieve a structure where a plurality of photoelectric conversion cells 50 are connected in series, the photoelectric conversion layer 14 is patterned in a rectangular strip shape by use of laser. The photoelectric conversion layer 14 is patterned in a rectangular strip shape formed by the third slit S3. The third slit S3 is formed such that YAG laser is irradiated in position lateral to the first slit S1, by which the transparent electrode layer 12 is segmentalized, by 50 μm, for instance. The YAG laser as used herein may preferably be such that the energy density is 0.7 J/cm² and the pulse frequency is 3 kHz, for instance.

As illustrated in FIG. 7C, a back-side electrode 16, formed of a transparent conductive oxide and a reflective metal, is formed on the photoelectric conversion layer 14. Note that the back-side electrode 16 is filled into the third slit S3. Thereby, the transparent electrode layer 12 and the back-side electrode 16 come into contact with each other and they are electrically connected. The back-side electrode 16 may be formed by use of a sputtering method or a CVD method, for instance.

To achieve a structure where a plurality of photoelectric conversion layer 14 are connected in series, the back-side electrode 16 is then patterned in a rectangular strip shape. The back-side electrode 16 is patterned in a rectangular strip shape formed by the fourth slit S4. The fourth slit S4 is formed such that YAG laser is irradiated in position lateral to the third slit S3, where the photoelectric conversion layer 14 is patterned, by 50 μm, for instance. To achieve a structure where the photoelectric conversion layer 14 is segmentalized in parallel, formed is a fifth slit S5 by which the photoelectric conversion layer 14 and the back-side electrode 16 formed within the second slit S2 used to segmentalized the transparent electrode layer 12 is segmentalized. The YAG laser as used herein may preferably be such that the energy density is 0.7 J/cm² and the pulse frequency is 4 kHz, for instance.

As described above, a photoelectric conversion cell 50 is formed by laminating the transparent electrode layer 12, the photoelectric conversion layer 14 and the back-side electrode 16 on the substrate 10.

Subsequently, as illustrated in FIG. 7D, a current-collecting wiring 18 is provided on the back-side electrode 16 of the photoelectric conversion cell 50 in such a manner that the current-collecting wiring 18 also extends over the photoelectric conversion cells 50. The current-collecting wiring 18 extends on the back-side electrode 16 such that the current-collecting wiring 18 lies across the second slit S2 and the fifth slit S5. Here, the current-collecting wiring 18 extends along a direction vertical to a distal edges at the both ends (see FIG. 1). Note, however, that in the vicinity of the vertical distal edge as shown in FIG. 1 the current-collecting wiring 18 does not lie across photoelectric conversion layers, which do not have the photoelectric conversion functions, and the second slits S2 and fifth slits S5 in the vicinity of said distal edge. The current-collecting wiring 18 is electrically connected to the back-side electrode 16 by use of solder that has been melted by ultrasound.

Then, as illustrated in FIG. 7E, the insulating member 20 extends, on top of the back-side electrode 16, from near the current-collecting wiring 18 to the placement position of the terminal box 32 in the center thereof along the second slit S2 extending direction in such a manner that the insulating member 20 lies across the fourth slit S4. Here, as illustrate in FIG. 1, the insulating member 20 extends horizontally from near the current-collecting wirings 18 at the both ends of the current-collecting wirings 18 towards the terminal box 32. In the present embodiment, the PET tape, which is used as the insulating member 20, is bonded to the back-side electrode 16.

As illustrated in FIG. 8F, the output wiring 22 extends, along a surface of the insulating member 20, from the current-collecting wirings 18 towards the center of the photoelectric conversion device 100. One end of the output wiring 22 is electrically connected to the current-collecting wiring 18 by use of solder melted by ultrasound, and the other end of the output wiring 22 is connected to an electrode terminal inside the terminal box 32 described later. Thereby, the electric power generated by a plurality of photoelectric conversion cells 50 is delivered to outside the photoelectric conversion device 100. At this time, in the region 70 where the current-collecting wiring 18 and the output wiring 22 of FIG. 1 are connected to each other, the current-collecting wiring 18 and the output wiring 22 are positioned such that the surface of the current-collecting wiring 18 vertical to the main surface of the substrate 10 and the surface of the output wiring 22 vertical to the main surface thereof are in contact with each other as shown in FIG. 4 and therefore they are electrically connected to each other. That is, the current-collecting wiring 18 and the output wiring 22 are positioned such that the current-collecting wiring 18 and the output wiring 22 do not overlap with each other above the main surface of the substrate 10 in the region 70 where the current-collecting wiring 18 and the output wiring 22 are connected to each other.

Then, as illustrated in FIG. 8G, an insulating coating material 24 is provided at a predetermined position and in a predetermined manner. The insulating coating material 24 extends in the first slit S1 extending direction so that the insulating coating material 24 can cover at least the transparent electrode 12, the photoelectric conversion layer 14, the back-side electrode 16, the current-collecting wiring 18 and the output wiring 22 located near an end-sealing material 26 described later. The PET tape is used as the insulating coating material 24.

Then, as illustrated in FIG. 8H, the end-sealing material 26 is provided at a predetermined position and in a predetermined manner. The end-sealing material 26 is disposed in the region where a photoelectric conversion cell 50 at the distal periphery of the photoelectric conversion device 100 is not formed. Here, such a region where the end-sealing material 26 is to be provided is about 7 mm to about 15 mm in width. To provide a portion where no photoelectric conversion cell 50 is formed at the distal periphery of the photoelectric conversion device 100, the periphery of the substrate 10 is first masked and then a film formation processing is performed so that the transparent electrode layer 12, the photoelectric conversion layer 14 and the back-side electrode 16 are not to be formed, when the photoelectric conversion cell 50 is formed. Or, after the photoelectric conversion cells 50 have been formed, photoelectric conversion cells 50 at the distal periphery of the photoelectric conversion device 100 may be removed by sandblast or etching. The end-sealing material 26 is provided, as described above, such that the hot-melt butyl is applied to the thus formed portion where no photoelectric conversion cell 50 is formed at the distal periphery of the photoelectric conversion device 100.

After the end-sealing material 26 has been applied, the back side of the photoelectric conversion device 100 is sealed by a back-side protective member 30. The sealing member 28 is filled into between the photoelectric conversion layer 14 and the back-side protective member 30, so that the back side of the photoelectric conversion device 100 is sealed by the back-side protective member 30. The sealing member 28 is first set in a region surrounded by the end-sealing material 26 of the back side of the photoelectric conversion device 100 such that the sealing member 28 having the same size as that of the region surrounded by the end-sealing material 26 or smaller than that thereof by 1 mm both in the vertical and horizontal directions. Then the back-side protective member 30 is so placed as to cover the back side of the photoelectric conversion device 100. Then an end of the output wiring 22 is pulled out of the back-side protective member 30 in order to connect the end of the output wiring 22 to the terminal box 32. Then a pressure is applied from a back-side protective member 30 side, and the back-side protective member 30 undergoes a vacuum laminating processing. Furthermore, the photoelectric conversion device 100 is heated and a bridge is formed by ethylene vinyl acetate (EVA), which is used as the sealing member 28. The heating process to form the bridge may preferably be done at 150° C. for about 30 minutes, for instance.

Then, as illustrated in FIG. 1, the terminal box 32 is mounted such that the terminal box 32 is bonded near the end of output wiring 22 pulled out of the back-side protective member 30 used to seal the photoelectric conversion device 100, using silicone or the like. The end of the output wiring 22 is electrically connected to the electrode terminal inside the terminal box 32, and an insulating resin is filled into a space in the terminal box 32 so as to cover the terminal box 32.

Through the processes described as above, the photoelectric conversion device 100 according to the present embodiment is formed.

Advantageous Effects

The following three advantageous effects are at least gained by employing the above-described photoelectric conversion device 100 and the method for fabricating the photoelectric conversion device 100.

1. As shown in FIG. 2 and FIG. 4, the current-collecting wiring 18 and the output wiring 22 are electrically connected to each other such that the surface of the current-collecting wiring 18 vertical to the main surface of the substrate 10 and the surface of the output wiring 22 vertical to the main surface thereof come in contact with each other. In other words, the current-collecting wiring 18 and the output wiring 22 are positioned such that the current-collecting wiring 18 and the output wiring 22 do not overlap with each other above the main surface of the substrate 10. As a result, the raised portion formed in the conventional practice where a current-collecting wiring and an output wiring 22 overlap with each other is not formed in the region 70 of FIG. 1. This structure according to the present embodiment can suppress the deformation and breakage of the back-side protective member 30 that may otherwise occur because the stress concentrates near the raised portion when a pressure is applied from the back-side protective member 30 side and the back-side protective member 30 undergoes the vacuum laminating processing. Hence, the reduction in yield on account of such deformation and breakage can be suppressed.

2. A peripheral part is sealed by the end-sealing material 26. This structure can prevent water content or corrosive material from entering the distal periphery. Thus, the environment resistance of the photoelectric conversion device 100 can be enhanced.

3. The insulating coating material 24 is provided so that the insulating coating material 24 can cover the transparent electrode 12, the photoelectric conversion layer 14, the back-side electrode 16, the current-collecting wiring 18 and the output wiring 22 located near the end-sealing material 26. Thereby, any possible adverse effect of a chemical reaction between the end-sealing material 26 and the sealing member 28 can be suppressed by provision of a portion covered with the insulating coating material 24. Thus, the environment resistance of the photoelectric conversion device 100 can be enhanced.

### Second Embodiment

(Structure of Photoelectric Conversion Device)

In the first embodiment, the current-collecting wiring 18 and the output wiring 22 are positioned such that the current-collecting wiring 18 and the output wiring 22 do not overlap with each other above the main surface of the substrate 10. Also, provided in the first embodiment is the photoelectric conversion device 100 having a high yield and a high productivity. However, these should not be considered as limiting. In a photoelectric conversion device according to a second embodiment, an output wiring 34 may have a connecting component 34a, at one end, whose width is larger than that of other part of the output wiring 34. Thereby, also provided in the second embodiment is a photoelectric conversion device 200 having a high yield and a high productivity. A description is hereunder given centering around features different from those of the first embodiment.

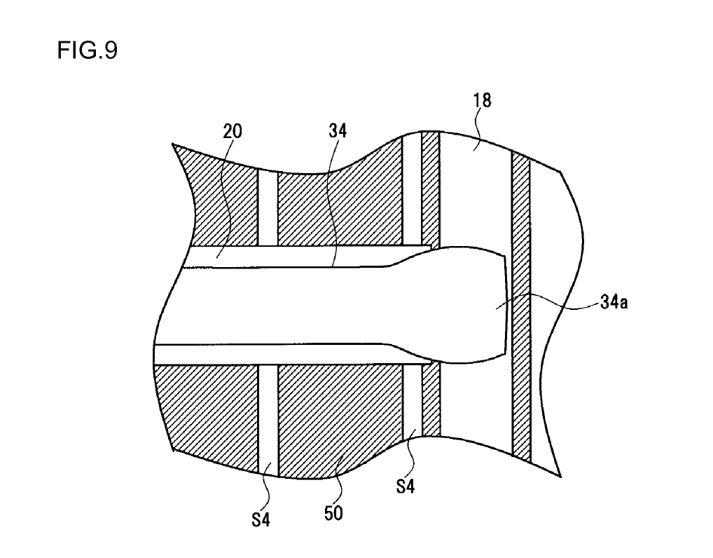

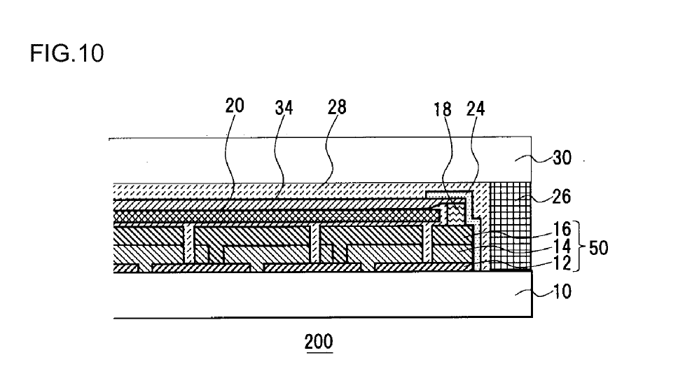

FIG. 9 and FIG. 10 each shows a characterizing portion of the photoelectric conversion device 200 according to the second embodiment of the present invention. FIG. 9 is a cross-sectional view taken along the line A-A of FIG. 1. FIG. 10 is a cross-sectional view taken along the line B-B of FIG. 1. Note that a sealing member 28 and a back-side protective member 30 are not depicted in FIG. 9 and FIG. 10. Also, for clarity of the structure thereof, the dimensions of each part is scaled differently from the actual dimensions in FIG. 9 and FIG. 10.

Similar to the second embodiment, in the second embodiment, a photoelectric conversion cell 50 comprised of a transparent electrode layer 12, a photoelectric conversion layer 14 and a back-side electrode 16 is formed on a substrate 10. And a current-collecting wiring 18 extends on the photoelectric conversion cells 50 located at the both ends of the substrate 10. Also, an insulating member 20 extends from near the current-collecting wiring 18 to the placement position of a terminal box 32 in the center of the current-collecting wiring 18, along a direction of a second slit S2.

The second embodiment differs from the first embodiment in that an output wiring 34 has the connecting component 34a, at one end, formed such the width is larger than that of the other part of the connecting component 34a. In contrast, the output wiring 22 according to the first embodiment has a fixed width. More specifically, if in the second embodiment a copper wiring covered with solder is used as the output wiring 34, the output wiring 34 has the connecting component 34a, at one end, whose width is larger than that of the copper wiring with copper used as a base material and whose thickness is smaller than that of the copper wiring.

The current-collecting wiring 18 and the output wiring 34 are positioned such that the current-collecting wiring 18 and the output wiring 22 overlap with each other. And the current-collecting wiring 18 and the output wiring 22 are electrically connected to each other.

After the output wiring 34 is connected to the current-collecting wiring 18, an insulating coating material 24 and an end-sealing material 26 are formed and the photoelectric conversion layer 14 is sealed between the substrate 10 and the back-side protective member 30 through the medium of the sealing member 28. Then the other end of the output wiring 34 pulled out of the back-side protective member 30 is connected to the terminal box 32.

Through the processes described as above, the photoelectric conversion device 200 according to the present embodiment is formed.

(A Method for Fabricating a Photoelectric Conversion Device)

In a method for fabricating the photoelectric conversion device 200 according to the second embodiment, the photoelectric conversion device 200 is fabricated such that an end of the output wiring 34 press-rolled and then the output wiring 34 is connected to the current-collecting wiring 18. A description is hereunder given centering around differences from the first embodiment.

Similar to the first embodiment, the photoelectric conversion cells 50 are formed by stacking the transparent electrode layer 12, the photoelectric conversion layer 14 and the back-side electrode 16 on the substrate 10, and then the current-collecting wiring 18 extends on the photoelectric conversion cells 50 located at the both ends of the substrate 10. Then, the insulating member 20 extends from near the current-collecting wiring 18 to the placement position of the terminal box 32 in the center thereof along the second slit S2 extending direction. In this manner, the photoelectric conversion device as shown in FIG. 7E is prepared.

Then, an output wiring 34 used in the second embodiment is prepared. A copper wiring, coated with solder, which has been cut to a predetermined length is prepared. Then a force or pressure enough to perform the press-rolling the copper wiring used as a base material is applied to an end of the copper wiring coated with solder. Thereby, the connecting component 34a can be formed at one end of the copper wiring coated with solder. The connecting component 34a is press-rolled such that the width of the connecting component 34a is larger than that of the copper wiring and the thickness thereof is smaller than that of the copper wiring.

The output wiring 34 prepared as above extends along the surface of the insulating member 20, from top of the current-collecting wirings 18 towards the center of the photoelectric conversion device 100 along the second slit S2 extending direction. The output wiring 34 is configured such that the connecting component 34a of the output wiring 34 is electrically connected to the current-collecting wiring 18 by use of solder that has been melted by ultrasound and such that the connecting component 34a thereof overlaps with the current-collecting wiring 18.

Then, similar to the first embodiment, the insulating coating material 24 is formed and the end-sealing material 26 is placed between the substrate 10 and the back-side protective member 30, thereby achieving a structure where a plurality of photoelectric conversion cells 50 are sealed. And the sealing member 28 is filled into the structure. Then the other end of the output wiring 34 pulled out of the back-side protective member 30 is connected to the terminal box 32, thereby forming the photoelectric conversion device 200 of the second embodiment.

(Advantageous Effects)

The following two advantageous effects are at least gained by employing the above-described photoelectric conversion device 200 and the method for fabricating the photoelectric conversion device 200.

1. The connecting component 34a is formed by press-rolling one end of the copper wiring coated with solder. As shown in FIG. 10, this reduces the thickness of the connecting component 34a in the output wiring 34, so that the height of the raised portion, namely the height of an overlapped portion where the current-collecting wiring 18 and the output wiring 34 are overlapped with each other, can be reduced. This structure according to the second embodiment can suppress the deformation and breakage of the back-side protective member 30 that may otherwise occur because the stress concentrates near the raised portion when a pressure is applied from the back-side protective member 30 side and the back-side protective member 30 undergoes the vacuum laminating processing. Hence, the reduction in yield on account of such deformation and breakage can be suppressed.

2. The connecting component 34a is formed at one end of the copper wiring coated with solder such that the width of the connecting component 34a is wider than that of the copper wiring. As shown in FIG. 9, this structure according to the second embodiment increases the contact area of the current-collecting wiring 18 and the output wiring 34, so that the contact resistance of the current-collecting wiring 18 and the output wiring 34 can be reduced. Thus, an increased amount of output can be produced from the photoelectric conversion device 200.

A photoelectric conversion device and a method for fabricating the photoelectric conversion device as combined in the following Items 1 to 8.

(Item 1) A photoelectric conversion device including:

a substrate;

a plurality of photoelectric conversion cells formed on a main surface of the substrate;

a current-collecting wiring formed on the plurality of photoelectric conversion cells;

an output wiring connected to the current-collecting wiring; and

a back-side protective member bonded to the plurality of photoelectric conversion cells via a sealing member in a manner such that the plurality of photoelectric conversion cells formed on the main surface of the substrate are interposed between the substrate and the back-side protective member via the sealing member,

wherein the current-collecting wiring and the output wiring are positioned and connected such that the current-collecting wiring and the output wiring do not overlap with each other above the main surface of the substrate, and

wherein at least one of the current-collecting wiring and the output wiring has asperities on a joint surface between the current-collecting wiring and the output wiring.

(Item 2) A photoelectric conversion device according to Item 1, wherein the current-collecting wiring is such that the current-collecting wiring has a first connecting component, which is recessed from an edge of the current-collecting wiring facing a center of the substrate, in a part of the current-collecting wiring with which the output wiring is connected,

wherein the output wiring has a second connecting component corresponding to the first connecting component, and

wherein the first connecting component and the second connecting component are placed such that the first connecting component and the second connecting component are in mesh with each other.

(Item 3) A photoelectric conversion device according to Item 1 or Item 2, wherein the current-collecting wiring is formed of a plurality of members and is configured such that the output wiring is placed among the plurality of members constituting current-collecting wiring and such that the output wiring is electrically connected to the current-collecting wiring.

(Item 4) A photoelectric conversion device according to any one of Item 1 to Item 3, wherein surfaces of the output wiring and the current-collecting wiring are covered with a solder, and

wherein the output wiring and the current-collecting wiring are connected via the solder.

(Item 5) A method for fabricating a photoelectric conversion device, the method including:

a process of forming a plurality of photoelectric conversion cells on a main surface of a substrate;

a process of forming a current-collecting wiring for collecting the currents generated by the plurality of photoelectric conversion cells;

a process of forming an output wiring for outputting power generated by the current-collecting wiring to the outside; and

bonding a back-side protective member to the plurality of photoelectric conversion cells via sealing member in a manner such that the plurality of photoelectric conversion cells formed on the main surface of the substrate are interposed between the substrate and the back-side protective member via the sealing member,

wherein the current-collecting wiring and the output wiring are positioned and connected such that the current-collecting wiring and the output wiring do not overlap with each other above the main surface of the substrate, and

wherein at least one of the current-collecting wiring and the output wiring has asperities on a joint surface between the current-collecting wiring and the output wiring.

(Item 6) A method, for fabricating a photoelectric conversion device, according to Item 5, wherein the current-collecting wiring is such that the current-collecting wiring has a first connecting component, which is recessed from an edge of the current-collecting wiring facing a center of the substrate, in a part of the current-collecting wiring with which the output wiring is connected,

wherein the output wiring has a second connecting component corresponding to the first connecting component, and

wherein the first connecting component and the second connecting component are placed and connected to each other such that the first connecting component and the second connecting component are in mesh with each other.

(Item 7) A method, for fabricating a photoelectric conversion device, according to Item 5 or Item 6, wherein the current-collecting wiring is formed of a plurality of members and is configured such that the output wiring is placed among the plurality of members constituting current-collecting wiring and such that the output wiring is electrically connected to the current-collecting wiring.

(Item 8) A method, for fabricating a photoelectric conversion device, according to any one of Item 5 to Item 7, wherein surfaces of the output wiring and the current-collecting wiring are covered with a solder, and

wherein the output wiring and the current-collecting wiring are connected via the solder.

What is claimed is:

1. A photoelectric conversion device including:
a substrate;
a plurality of photoelectric conversion cells formed on a main surface of the substrate;
a current-collecting wiring formed on the plurality of photoelectric conversion cells;
an output wiring connected to the current-collecting wiring; and
a back-side protective member bonded to the plurality of photoelectric conversion cells via a sealing member in a manner such that the plurality of photoelectric conversion cells are interposed between the substrate and the back-side protective member via the sealing member,
wherein the current-collecting wiring and the output wiring are positioned and connected such that the current-collecting wiring and the output wiring do not overlap with each other above the main surface of the substrate, and
wherein at least one of the current-collecting wiring and the output wiring has asperities on a joint surface between the current-collecting wiring and the output wiring.

2. A photoelectric conversion device according to claim 1, wherein the current-collecting wiring is such that the current-collecting wiring has a first connecting component, which is recessed from an edge of the current-collecting wiring facing a center of the substrate, in a part of the current-collecting wiring with which the output wiring is connected,
wherein the output wiring has a second connecting component corresponding to the first connecting component, and
wherein the first connecting component and the second connecting component are placed such that the first connecting component and the second connecting component are in mesh with each other.

3. A photoelectric conversion device according to claim 1, wherein the current-collecting wiring is formed of a plurality of members and is configured such that the output wiring is placed among the plurality of members constituting current-collecting wiring and such that the output wiring is electrically connected to the current-collecting wiring.

4. A photoelectric conversion device according to claim 1, wherein surfaces of the output wiring and the current-collecting wiring are covered with a solder, and
wherein the output wiring and the current-collecting wiring are connected via the solder.

5. A method for fabricating a photoelectric conversion device, the method including:
forming a plurality of photoelectric conversion cells on a main surface of a substrate;
forming a current-collecting wiring for collecting currents generated by the plurality of photoelectric conversion cells;
forming an output wiring for outputting power generated by the current-collecting wiring to the outside; and
bonding a back-side protective member to the plurality of photoelectric conversion cells via sealing member in a manner such that the plurality of photoelectric conversion cells are interposed between the substrate and the back-side protective member via the sealing member,
wherein the current-collecting wiring and the output wiring are positioned and connected such that the current-collecting wiring and the output wiring do not overlap with each other above the main surface of the substrate, and
wherein at least one of the current-collecting wiring and the output wiring has asperities on a joint surface between the current-collecting wiring and the output wiring.

6. A method, for fabricating a photoelectric conversion device, according to claim 5, wherein the current-collecting wiring is such that the current-collecting wiring has a first connecting component, which is recessed from an edge of the current-collecting wiring facing a center of the substrate, in a part of the current-collecting wiring with which the output wiring is connected,
wherein the output wiring has a second connecting component corresponding to the first connecting component, and
wherein the first connecting component and the second connecting component are placed and connected to each other such that the first connecting component and the second connecting component are in mesh with each other.

7. A method, for fabricating a photoelectric conversion device, according to claim 5, wherein the current-collecting wiring is formed of a plurality of members and is configured such that the output wiring is placed among the plurality of members constituting current-collecting wiring and such that the output wiring is electrically connected to the current-collecting wiring.

8. A method, for fabricating a photoelectric conversion device, according to claim 5, wherein surfaces of the output wiring and the current-collecting wiring are covered with a solder, and
wherein the output wiring and the current-collecting wiring are connected via the solder.
